(19) United States
(12) Patent Application Publication
(10) Pub. No.: US 2013/0241660 A1
(43) Pub. Date: Sep. 19, 2013

(54) Buck Up Power Converter

(71) Applicant: Pallab Midya, Palatine, IL (US)

(72) Inventor: Pallab Midya, Palatine, IL (US)

(73) Assignee: FAIRCHILD SEMICONDUCTOR CORPORATION, San Jose, CA (US)

(21) Appl. No.: 13/605,373

(22) Filed: Sep. 6, 2012

Related U.S. Application Data
(60) Provisional application No. 61/532,443, filed on Sep. 8, 2011.

(51) Int. Cl. H02M 3/158; H03F 3/19

(52) U.S. Cl. CPC H02M 3/1582; H03F 3/19
USPC 330/297; 323/299; 323/311

(57) ABSTRACT

Generally, this disclosure provides an apparatus, method and system for DC-DC conversion. The apparatus may include a switch network including a first plurality of switches configured to operate in a Buck mode to generate an output voltage that is less than an input voltage, and a second plurality of switches configured to operate in an Up mode to generate an output voltage that is greater than the input voltage. The apparatus of this example may further include controller circuitry configured to generate control signals to control the conduction state of the first plurality of switches and the second plurality of switches based on a variable reference signal indicative of power demands from a load coupled to the switch network.

### CROSS-REFERENCE TO RELATED APPLICATIONS

This application claims the benefit of U.S. Provisional Application No. 61/532,443 filed Sep. 8, 2011, which is incorporated by reference herein in its entirety.

### FIELD

The present disclosure relates to a DC-DC converter system that can operate in multiple modes.

### BACKGROUND

DC-DC converter systems convert a direct current (DC) input voltage to a DC output voltage at a different voltage level. The output voltage may typically be used as a supply voltage for a load such as, for example, an amplifier circuit. The capability to provide an output voltage that is higher than the input voltage may be desirable in some applications. For example, if the load is an RF power amplifier for a cell phone, the higher voltage may provide for increased talk time. Existing DC-DC converter systems, however, typically require the use of two inductors to generate an output voltage that exceeds the input voltage. This approach presents a problem though, since inductors are usually the largest component in the converter and there is a growing need for increased circuit miniaturization.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 depicts a Buck Up DC-DC converter system 100 consistent with the present disclosure;

FIG. 2 depicts controller circuitry according to one exemplary embodiment of the present disclosure;

FIG. 3 is a set of signal plots corresponding to an example of the converter system transitioning between Buck and Up modes;

FIG. 4 is block diagram of one exemplary system implementation for the Buck Up DC-DC converter system of the present disclosure; and

FIG. 5 illustrates a flowchart of operations consistent with one embodiment of the present disclosure.

Although the following Detailed Description will proceed with reference being made to illustrative embodiments, many alternatives, modifications, and variations thereof will be apparent to those skilled in the art.

### DETAILED DESCRIPTION

Generally, this disclosure provides an apparatus, method and system for DC-DC conversion. The converter may be configured to operate in two modes: a Buck mode that generates an output voltage (Vout) that is lower than the input voltage (Vin), and an Up mode that generates an output voltage that is higher than the input voltage. Advantageously, the converter described herein provides a single inductor solution for generating both higher and lower output voltages from an input voltage.

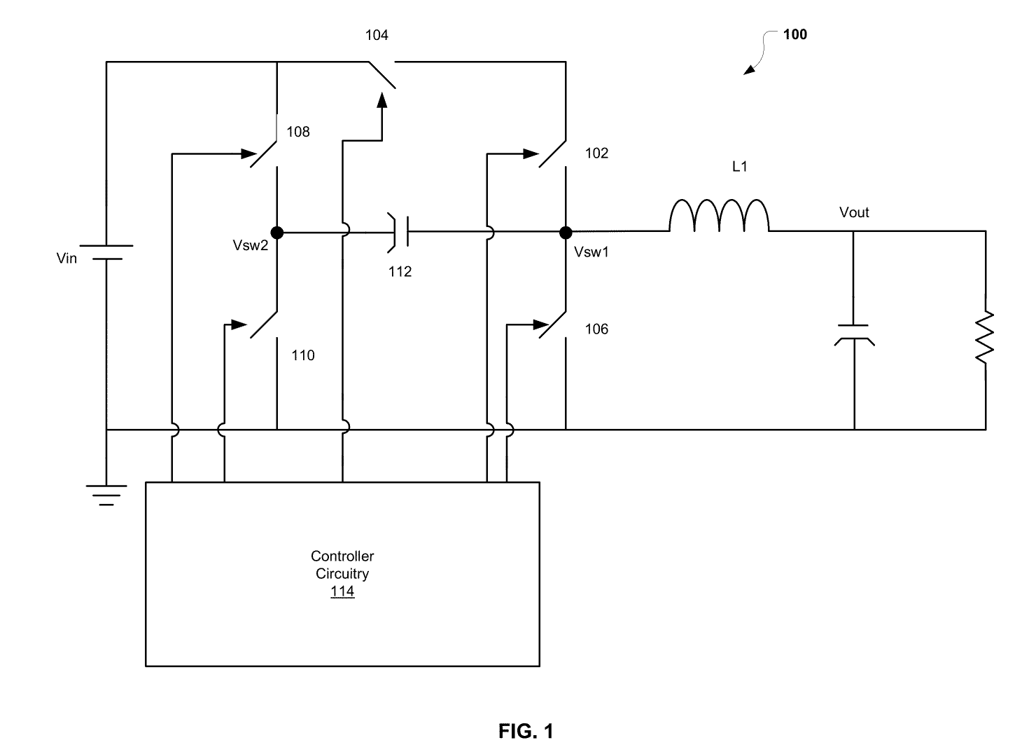

FIG. 1 depicts a Buck Up DC-DC converter system 100 consistent with the present disclosure. The Buck Up converter system 100 is configured to operate in two modes: a Buck mode that generates an output voltage that is lower than the input voltage, and an Up mode that generates an output voltage that is higher than the input voltage. In addition, the system 100 is configured to transition between Buck mode and Up mode on a cycle-by-cycle basis, which may advantageously provide a greater output voltage than would be otherwise provided by the input voltage. The system 100 may be optimized to minimize both the number of switches and the die area. Also advantageously, when the Buck Up converter is used to power RF devices, the switching noise is below the level required to meet the spectral mask of an RF power amplifier, such as those included with hand-held devices (e.g., 3G, 4G wireless devices, etc.).

The Buck Up converter system 100 generally includes a switching network that includes a plurality of switches that operate in Buck mode, and a plurality of switches that operate in Up mode. In the Buck mode, the switching waveform transitions between ground and the input voltage (0, Vin). In the Up mode the switching waveform transitions between the input voltage and approximately twice the input voltage (Vin, 2Vin). An L-C filter is disposed between the outputs of the switching network and the output node. In the example of FIG. 1, switches 102 and 104 are coupled together in series, and generally operate as the “high side” switches in Buck mode. Two “high side” switches (102 and 104) may be provided to eliminate the body diode effects of reverse voltages (false ON events), however, it should be appreciated that in other embodiments, switches 102 and 104 may be replaced with a single switch that is configured to block reverse voltages. Switch 106 is configured to operate as a “low side” switch in Buck mode. Switch 108 generally operates as the “high side” switches in up mode, and switch 110 is configured to operate as a “low side” switch in up mode. A charge up capacitor 112 is coupled between the Buck switches and the Up switches. Controller circuitry 114 is configured to generate PWM control signals to control the conduction state of the switch network to operate in Buck mode or up mode, as will be described in greater detail below.

In operation, if the system 100 is operating in Buck mode (Vout<Vin), switches 102/104 are switched ON to deliver Vin at the Vsw1 node (input to the inductor L), then switch 106 is turned ON (and switches 102/104 are turned OFF) so that Vsw1 node is at ground (e.g., 0 Volts). This process is dictated by the duty cycle of the PWM control signals that control switches 102/104 and 106. When the switches 102/104 are ON, switch 110 is also turned on which charges the up capacitor 112 to Vin. If the system 100 is operating in Up mode (Vout>Vin), switches 102/104 and 106 are turned OFF, and switch 108 is turned ON while switch 110 is turned OFF. Since capacitor 112 is already charged to Vin, turning switch 108 ON operates to deliver approximately 2*Vin at the Vsw1 node. Then switch 110, 104 and 102 are turned ON and switch 108 is turned OFF so that Vsw1 node is at Vin. Thus, in the Up mode, the Vsw1 node switches between approximately 2*Vin and Vin. This process is dictated by the duty cycle of the PWM control signals that control switches 108 and 110.

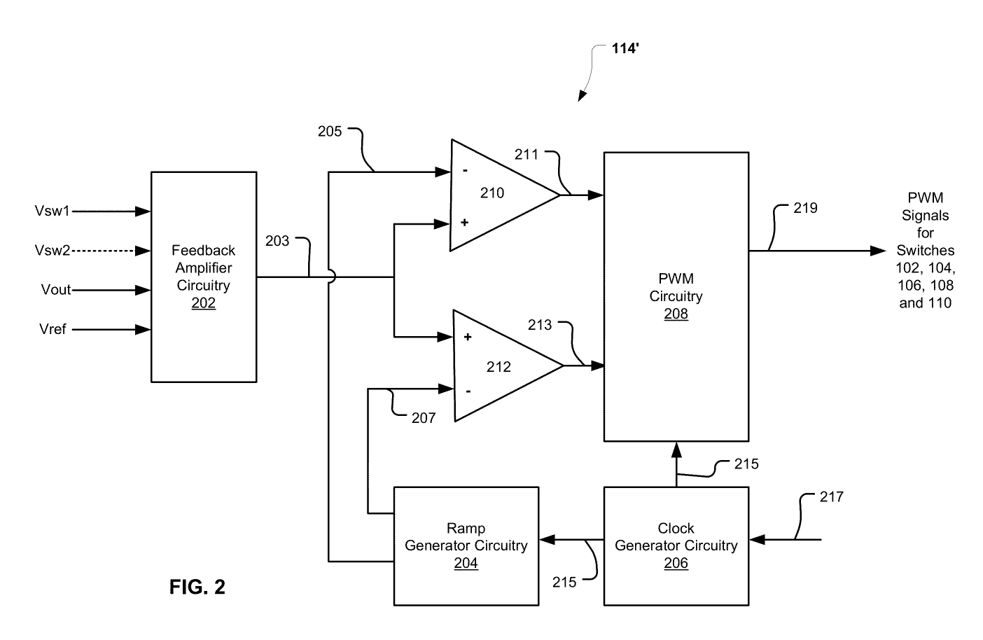

As will be appreciated, certain applications may momentarily demand more supply voltage than can be supplied by an input voltage source. By way of example, when Vin is a battery and the load is an RF power amplifier of a cell phone, if Vin has insufficient voltage for the required RF envelope, the RF amplifier may be incapable of generating sufficient power which may result in dropped calls, etc. Thus, there may be times when it is desirable to generate an output voltage that is greater than the input voltage to accommodate, for example, varying RF envelope and load conditions. As described above, the switch network may be controlled to operate in Buck mode (Vout<Vin) and Up mode (Vout>Vin). Accordingly, FIG. 2 depicts controller circuitry 114′ according to one exemplary embodiment of the present disclosure. As a general overview, the controller circuitry 114′ of this embodiment is generally configured to respond to RF envelope and load conditions to control the switch network in either Buck mode or up mode on a cycle-by-cycle basis. The controller circuitry 114′ includes feedback amplifier circuitry 202 that is generally configured to drive Vout to a reference voltage Vref, ramp generator circuitry 204 that is configured to generate complimentary ramp signals 205 and 207 and clock generator circuitry 206 configured to set the frequency of operation of various components of the controller circuitry 114′. In addition, comparator circuitry 210/212 and PWM circuitry 208 is included, which generally operate to control the ON/OFF state of the switch network depicted in FIG. 1. The operation of controller circuitry 114′ is described in greater detail below.

As an initial matter, Vref is generally defined as a reference voltage that responds to varying load conditions. Thus, for example, if the load requires a greater voltage than can be delivered by Vin, then the value of Vref may be adjusted upward. This causes the controller circuitry 114′ to control the switch network to operate in Up mode. If however, the load conditions change such that a higher output voltage is no longer required, then the value Vref may be adjusted downward, which causes the controller circuitry 114′ to control the switch network to operate in a Buck mode. Thus, Vref is generally defined as a load-dependant reference voltage whose value may change depending on the load demand.

With continued reference to FIG. 1, feedback amplifier circuitry is 202 is configured to generate an error signal 203 based on Vsw1, Vout and Vref. In some embodiments, feedback amplifier circuitry 202 may be configured to utilize Vsw2 in addition to, or as a substitute for, Vsw1, since the relationship between Vsw1 and Vsw2 may be determined by Vin and capacitor 112. Ramp generator circuitry 204 is configured to generate a first ramp signal 205 (referred to herein as a “lower ramp signal 205”) and a second ramp signal 207 (referred to herein as an “upper ramp signal 207”). The upper ramp signal 207 and the lower ramp signal 205 are generally complimentary signals. Over a given cycle (defined by the clock signal 215), the upper ramp signal 207 ramps down from a first voltage level (VL1) to a second voltage level (VL2), and the lower ramp signal ramps up from a third voltage level (VL3) to the second voltage level, where VL1>V12>VL3. The value of the voltage levels VL1, V12 and VL3 may be selected based on, for example, the gain of the feedback amplifier circuitry 202 so that the voltage of the error signal 203 falls within a predefined range between VL1 and VL3. The slope of the ramp signals 205 and 207 may be determined based on the expected slopes of the input signals to the feedback amplifier circuitry 202. For example, the slope of the upper ramp signal 207 may be proportional to −Vin and the slope of the lower ramp signal 205 may be proportional to +Vin. The dominant term in the slope of the error signal 203 is from the integral of Vin−Vsw1 which is +/−Vin. When the feedback signal 203 equals the upper ramp signal 207, controller circuitry 114 causes the converter to operate in the Up mode and the voltage at the Vsw1 node goes to approximately 2*Vin. The slope of the error signal 203 then becomes approximately proportional to −Vin which is approximately equal to the slope of the upper ramp signal 207. In the cycles when the error signal 203 equals the lower ramp signal 205, the controller circuitry 114 causes the converter to operate in the Buck mode and the voltage at the Vsw1 node goes to approximately 0. The slope of the error signal 203 is approximately proportional to +Vin which is approximately proportional to the slope of the lower ramp signal 205. If this were accomplished exactly, then at the end of each cycle the state of the system would be the same independent of the PWM duty ratio as well as the PWM mode. This results in maximum agility and minimum response time. The slope of the ramp signals 205/207 and the error signal 203 are inversely proportional to RC time constants and directly proportional to Vin. Thus, equal slope criteria may be met in spite of process variation of the RC component values and Vin voltage variations.

Clock signal generator circuitry 206 is configured to generate a clock signal 215 that generally controls the operating frequency of the ramp generator circuitry 204 and the PWM circuitry 208. The clock generator circuitry 206 may be configured to set the clock frequency of signal 215 based on an input signal 217. Input signal 217 may include, for example, system operating frequencies and clock generator circuitry 206 may be configured to set a clock frequency for signal 215 such that it avoids interference of system operating frequencies.

Comparator circuitry 210 is configured to compare the lower ramp signal 205 with the error signal 203 and generate first output signal 211. As a general matter, when signal 205 is less than signal 203, the first output signal 211 may be a first voltage level (e.g., logic “low” or 0), and when signal 205 and 203 are equal, the first output signal 211 may be a second voltage level (e.g., logic “high” or 1). Comparator circuitry 212 is configured to compare the upper ramp signal 207 with the feedback control signal 203 and generate second output signal 213. As a general matter, when signal 207 is less than signal 203, the second output signal 213 may be a first voltage level (e.g., logic “low” or 0), and when signal 207 and 203 are equal, the second output signal 213 may be a second voltage level (e.g., logic “high” or 1). PWM circuitry 208 is configured to generate PWM signals 219 to control the conduction of the switch network, based on the state of the first and second output signals 211 and 213, respectively. For example, if signal 211 changes states from low to high, PWM circuitry 208 may be configured to generate PWM signals 219 so that the switch network operates in Buck mode, and if signal 213 changes states from low to high, PWM circuitry 208 may be configured to generate PWM signals 219 so that the switch network operates in Up mode (described above). In some embodiments, PWM circuitry 208 may be configured to control the switch network in a discontinuous conduction mode and/or pulse frequency modulation (PFM) to improve efficiency.

The controller circuitry 114′ may be configured to operate in sensorless current mode (SCM) control. To that end, the feedback amplifier circuitry 202 may be configured to integrate the switching voltages on one or both sides of the capacitor 112, thus generating a representation of the AC part of the current and providing a low noise high bandwidth equivalent of current feedback without needing high gain bandwidth from the circuitry 202. In addition, the feedback amplifier circuitry 202 may utilize a single operational amplifier that provides proportional and integral feedback of the output voltage for full control.

In operation, at the start of a cycle, PWM circuitry may generate control signals 219 so that switches 102 and 104 are ON and switch 106 is OFF. This causes Vsw1 to approximately equal Vin. If Vref>Vin, the error signal 203 increases. Again, Vref may be greater than Vin if the load demand requires an increase in output voltage from the converter. When the voltage of the error signal 203 is increasing, it may, at some point be equal to voltage of the upper ramp signal 207. This may cause the second output signal 213 of the comparator circuitry 212 to change states (e.g., from low to high). PWM circuitry 208, in response to output signal 213 changing states, may control the switch network with appropriate PWM signals 219 so that the switch network operates in the Up mode (thus delivering approximately 2*Vin to the inductor). If Vref<Vin, the error signal 203 decreases. Again, Vref may be less than Vin if the load demand requires an decrease in output voltage from the converter, or if the load demand requires less voltage than was previously delivered in the Up mode. When the voltage of the error signal 203 is decreasing, it may, at some point be equal to voltage of the lower ramp signal 205. This may cause the first output signal 211 of the comparator circuitry 210 to change states (e.g., from low to high). PWM circuitry 208, in response to output signal 211 changing states, may control the switch network with appropriate PWM signals 219 so that the switch network operates in the Buck mode (thus delivering approximately 0 to the inductor). In any event, at the end of the PWM cycle, the upper and lower ramp signals (205, 207) may be reset and the PWM circuitry 208 may control the switch network in a manner described above at the start of the next cycle.

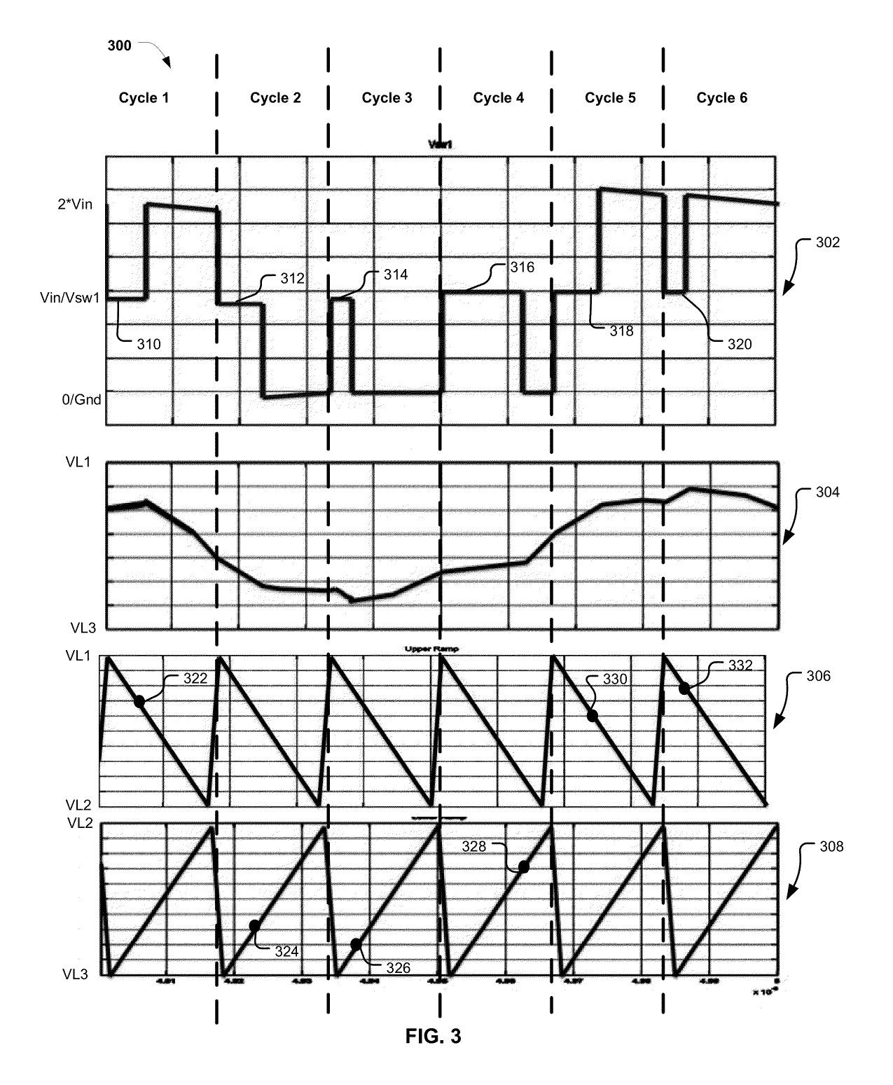

FIG. 3 is a set of signal plots 300 corresponding to an example of the converter system transitioning between Buck and Up modes. The signal plots 300 represent various waveforms through several PWM cycles (Cycle 1-Cycle 6). Signal plot 302 depicts the Vsw1 signal, signal plot 304 depicts the error signal (203), signal plot 306 depicts the upper ramp signal (207), and signal plot 308 depicts the lower ramp signal (205). At the start of Cycle 1, Vsw1 is equal to Vin (segment 310). The voltage of the error signal 304 ramps up, and equals the voltage of the upper ramp signal 306 at voltage level 322. A ramp up in the error signal indicates that Vref>Vin. This causes the converter system to enter the Up mode, and Vsw1 switches up to approximately 2*Vin for the remainder of Cycle 1. At the end of Cycle 1, the ramp signals 306 and 308 reset. At the start of Cycle 2, Vsw1 is equal to Vin (segment 312). The voltage of the error signal 304 ramps down, and equals the voltage of the lower ramp signal 308 at voltage level 324. A ramp down in the error signal indicates that Vref<Vin. This causes the converter system to enter the Buck mode, and Vsw1 switches down to approximately 0 Volts for the remainder of Cycle 2. At the end of Cycle 2, the ramp signals 306 and 308 reset. At the start of Cycle 3, Vsw1 is equal to Vin (segment 314). The voltage of the error signal 304 ramps down, and equals the voltage of the lower ramp signal 308 at voltage level 326. This causes the converter system to enter the Buck mode, and Vsw1 switches down to approximately 0 Volts for the remainder of Cycle 3. At the end of Cycle 3, the ramp signals 306 and 308 reset. At the start of Cycle 4, Vsw1 is equal to Vin (segment 316). The voltage of the error signal 304 is ramping up, but Vref is still less than Vin, thus the error signal equals the voltage of the lower ramp signal 308 at voltage level 328. This causes the converter system to enter the Buck mode, and Vsw1 switches down to approximately 0 Volts for the remainder of Cycle 4. At the end of Cycle 4, the ramp signals 306 and 308 reset. At the start of Cycle 5, Vsw1 is equal to Vin (segment 318). The voltage of the error signal 304 ramps up, and equals the voltage of the upper ramp signal 306 at voltage level 330. This causes the converter system to enter the up mode, and Vsw1 switches up to approximately 2*Vin for the remainder of Cycle 5. At the end of Cycle 5, the ramp signals 306 and 308 reset. At the start of Cycle 6, Vsw1 is equal to Vin (segment 320). The voltage of the error signal 304 ramps up, and equals the voltage of the upper ramp signal 306 at voltage level 332. This causes the converter system to enter the up mode, and Vsw1 switches up to approximately 2*Vin for the remainder of Cycle 6. At the end of Cycle 6, the ramp signals 306 and 308 reset. This process may continue during operation of the converter system.

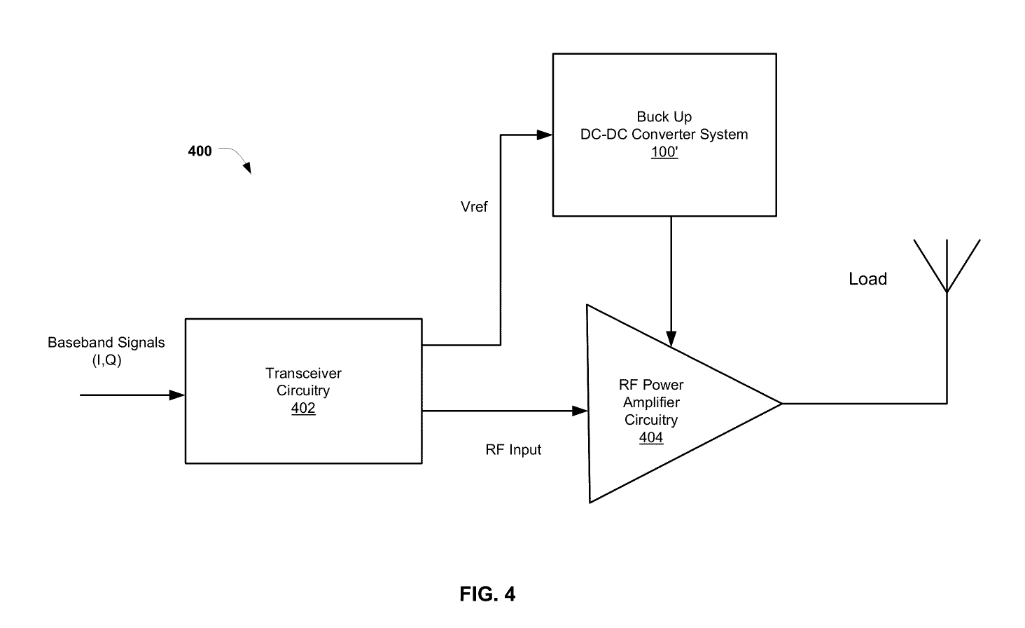

FIG. 4 is block diagram of one exemplary system implementation 400 for the Buck Up DC-DC converter system of the present disclosure. In the example of FIG. 4, the Buck Up DC-DC converter system 100′ is utilized as a power supply for RF power amplifier circuitry 404. The system 400 may include transceiver circuitry configured to send and receive RF baseband signals (I,Q). The transceiver circuitry 402 may also be configured to generate RF input signals to the RF amplifier circuitry 404. Depending on the RF envelope when sending RF signals, the transceiver circuitry 402 may also be configured to generate Vref indicative of the power demands of the RF amplifier circuitry 404. As described above, the Buck Up DC-DC converter system 100′ is configured to utilize Vref to switch between a Buck mode and an Up mode. Of course, the topology of FIG. 4 is only provided as an example implementation. The converter system described herein may be used in any system, circuit, IC, etc., where momentary increases in power output are desirable or required. For example, in a battery system where Vin represents the battery voltage, the converter system described herein may operate primarily in Buck mode while the charge on the battery remains relatively high. But as the battery charge is depleted, the converter system may operate in the Up mode, as required, to supplement the depleted battery. The terms “circuitry” or “circuit”, as used in any embodiment herein, may comprise, for example, singly or in any combination, hardwired circuitry, programmable circuitry, state machine circuitry, and/or circuitry available in a larger system, for example, discrete elements that may be included as part of an integrated circuit. A module, as used in any embodiment herein, may be embodied as circuitry. In addition, any of the switch devices described herein may include MOSFET-type transistor devices (including PMOS and/or NMOS devices), BJT transistor devices, and/or any type of known or after-developed switch circuitry that is configured to controllable change conduction states, etc.

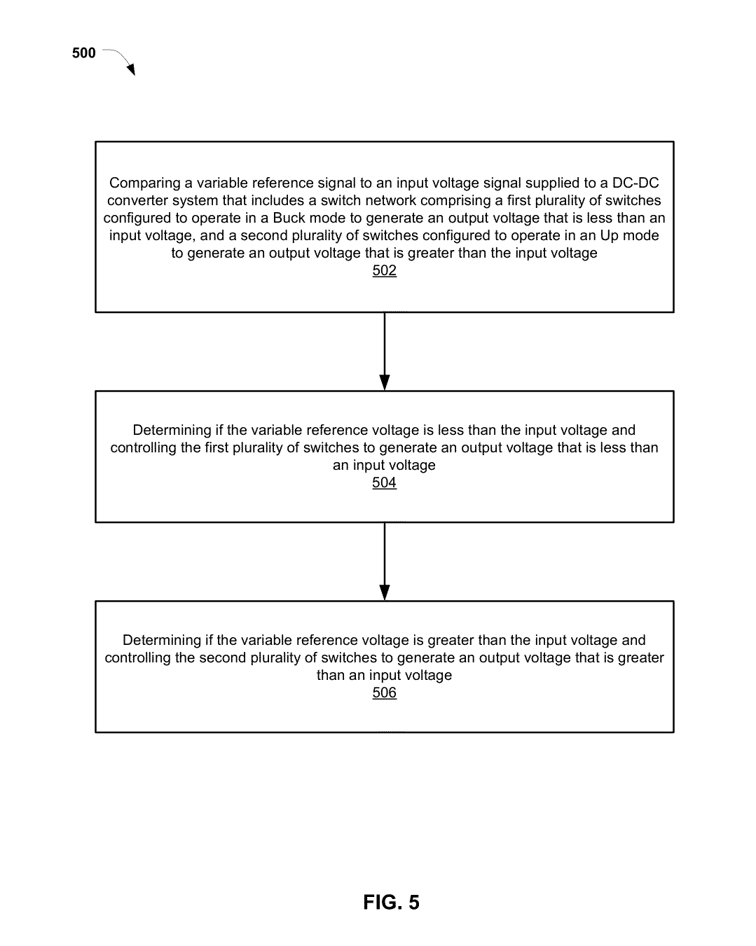

FIG. 5 illustrates a flowchart 500 of operations consistent with one embodiment of the present disclosure. Operations of this embodiment may include comparing a variable reference signal to an input voltage signal supplied to a DC-DC converter system that includes a switch network comprising a first plurality of switches configured to operate in a Buck mode to generate an output voltage that is less than an input voltage, and a second plurality of switches configured to operate in an up mode to generate an output voltage that is greater than the input voltage 502. The variable reference signal indicative of power demands from a load coupled to the switch network. Operations may also include determining if the variable reference voltage is less than the input voltage and controlling the first a plurality of switches to generate an output voltage that is less than an input voltage 504. Operations of this embodiment may also include determining if the variable reference voltage is greater than the input voltage and controlling the second a plurality of switches to generate an output voltage that is greater than an input voltage 406.

While FIG. 5 illustrates various operations according to one embodiment, it is to be understood that not all of these operations are necessary. Indeed, it is fully contemplated herein that in other embodiments of the present disclosure, the operations described herein may be combined in a manner not specifically shown in any of the drawings, but still fully consistent with the present disclosure. Thus, claims directed to features and/or operations that are not exactly shown in one drawing are deemed within the scope and content of the present disclosure.

Thus, the present disclosure provides an apparatus, method and system for DC-DC conversion. According to one aspect there is provided an apparatus. The apparatus may include a switch network including a first plurality of switches configured to operate in a Buck mode to generate an output voltage that is less than an input voltage, and a second plurality of switches configured to operate in an Up mode to generate an output voltage that is greater than the input voltage. The apparatus of this example may further include controller circuitry configured to generate control signals to control the conduction state of the first plurality of switches and the second plurality of switches based on a variable reference signal indicative of power demands from a load coupled to the switch network.

According to another aspect there is provided a method. The method may include comparing a variable reference signal to an input voltage signal supplied to a DC-DC converter apparatus that includes a switch network comprising a first plurality of switches configured to operate in a Buck mode to generate an output voltage that is less than the input voltage, and a second plurality of switches configured to operate in an Up mode to generate an output voltage that is greater than the input voltage; wherein the variable reference signal is indicative of power demands from a load coupled to the switch network. The method of this example may also include determining if the variable reference voltage is less than the input voltage and controlling the first plurality of switches to generate the output voltage that is less than an input voltage. The method of this example may further include determining if the variable reference voltage is greater than the input voltage and controlling the second plurality of switches to generate the output voltage that is greater than the input voltage.

According to another aspect there is provided a system. The system may include a transceiver circuit configured to convert a baseband signal to a radio frequency (RF) signal; an RF power amplifier circuit coupled to the transceiver circuit and configured to amplify the RF signal; and a DC-DC converter circuit configured to provide a supply voltage to the RF power amplifier circuit based on a variable reference signal provided by the transceiver circuit. The DC-DC converter circuit of this example may also include a switch network comprising a first plurality of switches configured to operate in a Buck mode to generate the supply voltage that is less than an input voltage, and a second plurality of switches configured to operate in an Up mode to generate the supply voltage that is greater than the input voltage. The DC-DC converter circuit of this example may further include controller circuitry configured to generate control signals to control the conduction state of the first plurality of switches and the second plurality of switches based on the variable reference signal indicative of power demands from the RF power amplifier circuit.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. A DC-DC converter apparatus, comprising:
a switch network comprising a first plurality of switches configured to operate in a Buck mode to generate an output voltage that is less than an input voltage, and a second plurality of switches configured to operate in an Up mode to generate said output voltage that is greater than said input voltage; and
controller circuitry configured to generate control signals to control the conduction state of said first plurality of switches and said second plurality of switches based on a variable reference signal indicative of power demands from a load coupled to said switch network.

2. The apparatus of claim 1, further comprising a filter network coupled to said switch network, said filter network configured to smooth said output voltage wherein said filter network comprises a capacitor and a single inductor.

3. The apparatus of claim 1, wherein said control signals are pulse width modulation (PWM) signals.

4. The apparatus of claim 1, wherein said control signals are pulse frequency modulation (PFM) signals.

5. The apparatus of claim 1, wherein said controller circuitry may further be configured to operate said switch network in a discontinuous conduction mode.

6. The apparatus of claim 1, wherein said second plurality of switches is further configured to operate in an Up mode to generate said output voltage that is less than two times said input voltage.

7. The apparatus of claim 1, wherein said load is a power amplifier circuit.

8. A method, comprising:
comparing a variable reference signal to an input voltage signal supplied to a DC-DC converter apparatus that includes a switch network comprising a first plurality of switches configured to operate in a Buck mode to generate an output voltage that is less than said input voltage, and a second plurality of switches configured to operate in an Up mode to generate said output voltage that is greater than said input voltage; wherein said variable reference signal is indicative of power demands from a load coupled to said switch network;
determining if said variable reference voltage is less than said input voltage and controlling said first plurality of switches to generate said output voltage that is less than an input voltage; and
determining if said variable reference voltage is greater than said input voltage and controlling said second plurality of switches to generate said output voltage that is greater than said input voltage.

9. The method of claim 8, further comprising smoothing said output voltage with a filter network comprising a capacitor and a single inductor.

10. The method of claim 8, wherein said first and said second plurality of switches are controlled by pulse width modulation (PWM) signals.

11. The method of claim 8, wherein said first and said second plurality of switches are controlled by pulse frequency modulation (PFM) signals.

12. The method of claim 8, further comprising operating said switch network in a discontinuous conduction mode.

13. The method of claim 8, further comprising operating said second plurality of switches in an Up mode to generate said output voltage that is less than two times said input voltage.

14. The method of claim 8, wherein said load is a power amplifier circuit.

15. A system comprising:
a transceiver circuit configured to convert a baseband signal to a radio frequency (RF) signal;
an RF power amplifier circuit coupled to said transceiver circuit and configured to amplify said RF signal; and
a DC-DC converter circuit configured to provide a supply voltage to said RF power amplifier circuit based on a variable reference signal provided by said transceiver circuit, said DC-DC converter circuit comprising:
a switch network comprising a first plurality of switches configured to operate in a Buck mode to generate said supply voltage that is less than an input voltage, and a second plurality of switches configured to operate in an Up mode to generate said supply voltage that is greater than said input voltage; and
controller circuitry configured to generate control signals to control the conduction state of said first plurality of switches and said second plurality of switches based on said variable reference signal indicative of power demands from said RF power amplifier circuit.

16. The system of claim 15, further comprising a filter network coupled to said switch network, said filter network configured to smooth said supply voltage wherein said filter network comprises a capacitor and a single inductor.

17. The system of claim 15, wherein said control signals are pulse width modulation (PWM) signals.

18. The system of claim 15, wherein said control signals are pulse frequency modulation (PFM) signals.

19. The system of claim 15, wherein said controller circuitry may further be configured to operate said switch network in a discontinuous conduction mode.

20. The system of claim 15, wherein said second plurality of switches is further configured to operate in an Up mode to generate said output voltage that is less than two times said input voltage.
